(19) United States
(12) Patent Application Publication
(10) Pub. No.: US 2023/0136775 A1
(43) Pub. Date: May 4, 2023

(54) METHODS AND SYSTEMS FOR AN ELECTRIC CHARGING AND METERING DEVICE

(71) Applicant: BETA AIR, LLC, South Burlington, VT (US)

(72) Inventor: Herman Wiegman, SOUTH BURLINGTON, VT (US)

(73) Assignee: BETA AIR, LLC, South Burlington, VT (US)

(21) Appl. No.: 17/515,502

(22) Filed: Oct. 31, 2021

(51) Int. Cl. H02J 7/00; G01R 21/133; B60L 53/16; B60L 53/66; B60L 53/62; B64F 1/36

(52) U.S. Cl. CPC H02J 7/0047; H02J 7/0042; H02J 7/00032; G01R 21/133; B60L 53/16; B60L 53/66; B60L 53/62; B64F 1/362; B60L 53/665

(57) ABSTRACT

An electric charging and metering device, including a charging connector, the charging connector configured to connect a charger to an electric aircraft; a sensor; and a processor. The charging connector including a direct current pin and an alternating current pin. The sensor communicatively connected to the charging connector. Additionally, the sensor configured to: monitor the direct current pin and the alternating current pin; measure an energy datum, the energy datum relating to a property of the charger, the charging connector electrically connected to the charger; and transmit the energy datum to a processor. The processor configured to receive the energy datum and calculate an electricity usage of the charger.

### FIELD OF THE INVENTION

The present invention generally relates to the field of charging electric vehicles. In particular, the present invention is directed to methods and systems for an electric charging and metering device.

### BACKGROUND

In electric vehicle charging systems, there exists a need to keep track of the energy output by the charging system. This may be to track wear and tear on the charging system, or to bill a user for the energy output by the charging system. A failure to accurately track this data can lead to an excessively worn charging system, or a user being under billed for the energy that they used. Existing solutions for an electric charging and metering device do not resolve this issue in a satisfactory manner.

### SUMMARY OF THE DISCLOSURE

In an aspect, an electric, charging and metering device, including: a charging connector, the charging connector configured to connect a charger to an electric aircraft, the charging connector including: a direct current pin; and an alternating current pin; a sensor, the sensor communicatively connected to the charging connector, the sensor configured to: monitor the direct current pin and the alternating current pin; measure an energy datum, the energy datum relating to a property of the charger, the charging connector electrically connected to the charger; and transmit the energy datum to a processor; and the processor, the processor configured to: receive the energy datum; and calculate an electricity usage of the charger.

In another aspect, A method of electric charger monitoring, including: monitoring a direct current pin, the direct current pin on a charging connector; monitoring an alternating current pin, the alternating current pin on the charging connector; measuring an energy datum relating to a property of a charger; transmitting the energy datum to a processor; and calculating an electricity usage of the charger based on the energy datum.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a block diagram of an embodiment of a charging system;

FIG. 2 is a diagram of the face of a charging connector;

FIG. 3 is a diagram of another embodiment of a charging system;

FIG. 4 illustrates a flow chart of a method of electric charger monitoring;

FIG. 5 is a block diagram of an exemplary flight controller;

FIG. 6 is a block diagram of an exemplary machine learning module; and

FIG. 7 is a block diagram of a computing system that can be used to implement any one or more of the methodologies disclosed herein and any one or more portions thereof.

The drawings are not necessarily to scale and may be illustrated by phantom lines, diagrammatic representations and fragmentary views. In certain instances, details that are not necessary for an understanding of the embodiments or that render other details difficult to perceive may have been omitted.

### DETAILED DESCRIPTION

Aspects of the present disclosure can be used to meter and monitor an electric vehicle charging device. Aspects of the present disclosure can also be used to prepare an invoice documenting the energy used by an electric vehicle charging device.

Aspects of the present disclosure allow for metering to be stopped by a processor when a disruption element is detected. Exemplary embodiments illustrating aspects of the present disclosure are described below in the context of several specific examples.

At a high level, aspects of the present disclosure are directed to systems and methods for metering a charging device for an electronic vehicle. In an embodiment, charging connector includes a sensor that measures an energy datum and a processor which calculates a value based on the energy datum.

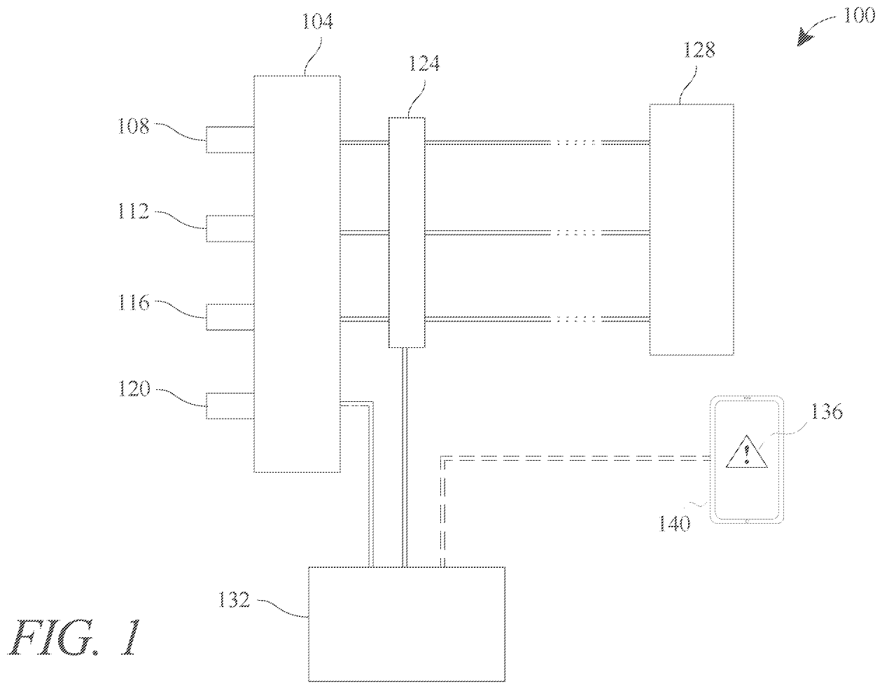

FIG. 1 shows a block diagram of an embodiment of charging system 100. Charging system 100 includes a charging connector 104. Charging connector 104 may include direct current (DC) pin 108 and alternating current (AC) pin 112. Charging connector 104 is configured to electrically connect an electric charger to an electric aircraft to facilitate charging of that electric aircraft. In some embodiments, charging connector 104 may include both DC pin 108 and AC pin 112. In other embodiments, charging connector 104 may only include one of DC pin 108 and AC pin 112. In yet other embodiments, charging connector 104 may include multiple of AC pin 112 and/or multiple of DC pin 108. AC pin 112 and DC pin 108 are disposed on charging connector 104. In some embodiments, charging connector 104 may include further pins, such as, for example, a ground pin 116, or a proximity detection pin 120.

With continued reference to FIG. 1, DC pin 108 supplies DC power. “DC power,” for the purposes of this disclosure refers, to the one-directional flow of charge. For example, in some embodiments, DC pin 108 may supply power with a constant current and voltage. As another example, in other embodiments, DC pin 108 may supply power with varying current and voltage, or varying currant constant voltage, or constant currant varying voltage. In another embodiment, when charging connector is charging certain types of batteries, DC pin 108 may support a varied charge pattern. This involves varying the voltage or currant supplied during the charging process in order to reduce or minimize battery degradation. AC pin 112 supplies AC power. For the purposes of this disclosure, “AC power” refers to the bi-directional flow of charge, where the flow of charge is periodically reversed. AC pin 112 may supply AC power at a variety of frequencies. For example, in a non-limiting embodiment, AC pin 112 may supply AC power with a frequency of 50 Hz. In another non-limiting embodiment, AC pin 112 may supply AC power with a frequency of 60 Hz. One of ordinary skill in the art, upon reviewing the entirety of this disclosure, would realize that AC pin 112 may supply a wide variety of frequencies. AC power produces a waveform when it is plotted out on a current vs. time or voltage vs. time graph. In some embodiments, the waveform of the AC power supplied by AC pin 112 may be a sine wave. In other embodiments, the waveform of the AC power supplied by AC pin 112 may be a square wave. In some embodiments, the waveform of the AC power supplied by AC pin 112 may be a triangle wave. In yet other embodiments, the waveform of the AC power supplied by AC pin 112 may be a sawtooth wave. The AC power supplied by AC pin 112 may, in general have any waveform, so long as the wave form produces a bi-directional flow of charge. For the purposes of this disclosure, “supply,” “supplies,” “supplying,” and the like, include both currently supplying and capable of supplying. For example, a live pin that “supplies” DC power need not be currently supplying DC power, it can also be capable of supplying DC power.

With continued reference to FIG. 1, in some embodiments, charging connector 104 may include a ground pin 116. A ground pin 116 is an electronic connector that is connected to ground. For the purpose of this disclosure, “ground” is the reference point from which all voltages for a circuit are measured. “Ground” can include both a connection the earth, or a chassis ground, where all of the metallic parts in a device are electrically connected together. In some embodiments, “ground” can be a floating ground. For instance, a chassis ground may be a floating ground when the potential is not equal to earth ground. In some embodiments, the negative pole in a DC circuit may be grounded. A “grounded connection,” for the purposes of this disclosure, is an electrical connection to “ground.” A circuit may be grounded in order to increase safety in the event that a fault develops. Speaking generally, a grounded connection allows electricity to pass through the grounded connection to ground instead of through, for example, a human that has come into contact with the circuit. Additionally, grounding a circuit helps to stabilize voltages within the circuit.

With continued reference to FIG. 1, for the purposes of this disclosure, a “pin” may be any type of electrical connector. An electrical connector is a device used to join electrical conductors to create a circuit. As a non-limiting example, in some embodiments, DC pin 108 and/or AC pin 112 may be the male component of a pin and socket connector. In other embodiments, DC pin 108 and/or AC pin 112 may be the female component of a pin and socket connector. As a further example of an embodiment, DC pin 108 and/or AC pin 112 may have a keying component. A keying component is a part of an electrical connector that prevents the electrical connector components from mating in an incorrect orientation. As a non-limiting example, this can be accomplished by making the male and female components of an electrical connector asymmetrical. Any or all of the DC pin 108 and/or AC pin 112 may have a keying component. Additionally, in some embodiments, DC pin 108 and/or AC pin 112 may include a locking mechanism. For instance, as a non-limiting example, any or all of DC pin 108 and/or AC pin 112 may include a locking mechanism to lock the pins in place. Additionally, the locking mechanism may, for example, be triggered by a lever. In another embodiment, for example, the locking mechanism could be triggered by an electronic or radio signal. DC pin 108 and/or AC pin 112 may each be any type of the various types of electrical connectors disclosed above, or they could all be the same type of electrical connector. One of ordinary skill in the art would understand that a wide variety of electrical connectors may be suitable for this application.

With continued reference to FIG. 1, DC pin 108, and AC pin 112 are electrically connected to sensor 124. In some embodiments, charging connector 104 may include a DC pin 108 or an AC pin 112, but not both; in this case, sensor 124 may be electrically connected to whichever of DC pin 108 and AC pin 112 is included in charging connector 104. Sensor 124 may monitor DC pin 108 and/or AC pin 112 through its electrical connection. Sensor may be consistent with any other sensor described in this disclosure.

With continued reference to FIG. 1, sensor 124 measures an energy datum. For the purposes of this disclosure, an “energy datum” is a datum representing a quantifiable element of energy provided by or contained by charger 128 or charging connector 104. In some embodiments, energy datum may relate to a property of the charger. For the purposes of this disclosure, “relating to a property of the charger” may include any electronic property of the charger, such as current, voltage, or stored energy, and it may include any electronic property of the charger, such as current or voltage, or the like. As a non-limiting example, sensor 124 may measure instantaneous current through DC pin 108. In an embodiment, sensor 124 may be a current sensor such as an ammeter. In another embodiment, sensor 124 may be an electronic battery sensor; the electronic battery sensor electronically connected to a power source within charger 128. Sensor 124 may be an electronic battery sensor consistent with the battery management system disclosed in U.S. patent application Ser. No. 17/108,798, filed on Dec. 1, 2020, entitled “Systems and Methods for a Battery Management System Integrated in a Battery Pack Configured for Use in an Electric Aircraft” and incorporated hereby by reference in its entirety. “Electronically connected,” for the purposes of this disclosure, means that electricity is able to flow (directly or indirectly) between the connected elements. An electronic battery sensor may monitor a variety of data concerning the battery it is attached to such as, for example, current, voltage, state of charge, and battery health.

With continued reference to FIG. 1, in another embodiment, sensor 124 may measure instantaneous current through AC pin 112 In cases where charging connector 104 has both a DC pin 108 and an AC pin 112, then sensor may measure the instantaneous current through each of the DC pin 108 and the AC pin 112. As another non-limiting example, sensor 124 may measure the power supplied by the DC pin 108 and/or AC pin 112. As another non-limiting example, sensor 124 may measure the stored energy of charger 128.

With continued reference to FIG. 1, sensor 124 may be part of a sensor suite. Sensor suite may include a sensor or plurality thereof that may detect voltage, current, resistance, capacitance, temperature, or inductance; detection may be performed using any suitable component, set of components, and/or mechanism for direct or indirect measurement, including without limitation comparators, analog to digital converters, any form of voltmeter, or the like. Sensor suite may include digital sensors, analog sensors, or a combination thereof. Sensor suite may include digital-to-analog converters (DAC), analog-to-digital converters (ADC, A/D, A-to-D), a combination thereof, or other signal conditioning components used in transmission of a resistance datum over wired or wireless connection.

With continued reference to FIG. 1, Sensor suite may measure an electrical property at an instant, over a period of time, or periodically. Sensor suite may be configured to operate at any of these detection modes, switch between modes, or simultaneous measure in more than one mode.

With continued reference to FIG. 1, sensor suite may include thermocouples, thermistors, thermometers, passive infrared sensors, resistance temperature sensors (RTD's), semiconductor based integrated circuits (IC), a combination thereof or another undisclosed sensor type, alone or in combination. Temperature, for the purposes of this disclosure, and as would be appreciated by someone of ordinary skill in the art, is a measure of the heat energy of a system. Temperature, as measured by any number or combinations of sensors present within sensor suite, may be measured in Fahrenheit (° F.), Celsius (° C.), Kelvin (° K), or another scale alone or in combination. The temperature measured by sensors may comprise electrical signals which are transmitted to their appropriate destination through a wireless or wired connection.

With continued reference to FIG. 1, sensor 124 may be electronically connected to a processor 132. In this embodiment, sensor 124 may transmit the energy datum to processor 132 using this electric connection. In another embodiment, sensor 124 may wirelessly transmit the energy datum to the processor 132. This can be accomplished, for example, using any suitable wireless communication technology, such as radio waves, Bluetooth, or WiFi. One of ordinary skill in the art, upon reviewing the entirety of this disclosure, would recognize that a variety of wireless communication technologies are suitable for this application.

With continued reference to FIG. 1, processor 132 receives the energy datum from the resistance sensor. As mentioned above, this may occur via any suitable wired or wireless communication technology. Processor 132 calculates the energy usage of charger 128. This can be done by, as a non-limiting example, integrating the power output over time. In another embodiment, processor 132 may subtract the stored energy in charger 128 from after charging from the stored energy in charger 128 from before charging. In this embodiment, stored energy in charger 128 from before charging may be a first energy datum, and stored energy in charger 128 from after charging may be a second energy datum. Alternatively, both the stored energy in charger 128 from before charging and the stored energy in charger 128 from after charging may be considered to be part of a single energy datum.

With continued reference to FIG. 1, in some embodiments, processor 132 may be implemented using an analog circuit. For example, in some embodiments processor 132 may be implemented using an analog circuit using operational amplifiers, comparators, transistors, or the like. In some embodiments, processor 132 may be implemented using a digital circuit having one or more logic gates. In some embodiments, controller may be implemented using a combinational logic circuit, a synchronous logic circuit, an asynchronous logic circuit, or the like. In other embodiments, processor 132 may be implemented using an application specific integrated circuit (ASIC). In yet other embodiments, processor 132 may be implemented using a field programmable gate array (FPGA) and the like.

With continued reference to FIG. 1, in some embodiments, processor 132 may be a computing device, flight controller, processor, control circuit, or the like. With continued reference to FIG. 1, processor 132 may include any computing device as described in this disclosure, including without limitation a microcontroller, microprocessor, digital signal processor (DSP) and/or system on a chip (SoC) as described in this disclosure. Computing device may include, be included in, and/or communicate with a mobile device such as a mobile telephone or smartphone. processor 132 may include a single computing device operating independently, or may include two or more computing device operating in concert, in parallel, sequentially or the like; two or more computing devices may be included together in a single computing device or in two or more computing devices. processor 132 may interface or communicate with one or more additional devices as described below in further detail via a network interface device. Network interface device may be utilized for connecting processor 132 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. processor 132 may include but is not limited to, for example, a computing device or cluster of computing devices in a first location and a second computing device or cluster of computing devices in a second location. processor 132 may include one or more computing devices dedicated to data storage, security, distribution of traffic for load balancing, and the like. processor 132 may distribute one or more computing tasks as described below across a plurality of computing devices of computing device, which may operate in parallel, in series, redundantly, or in any other manner used for distribution of tasks or memory between computing devices.

With continued reference to FIG. 1, processor 132 may be configured to perform any method, method step, or sequence of method steps in any embodiment described in this disclosure, in any order and with any degree of repetition. For instance, processor 132 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. processor 132 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

With continued reference to FIG. 1, processor 132 may be configured to display a visual alert 136 to a display 140 when resistance datum falls below the threshold resistance datum. Display 140 may include any display known in the art. Display 140 may be disposed on a charging device (e.g. charger 128). In another embodiment, display 140 may be disposed on a mobile device such as a smartphone or tablet. In another embodiment, display 140 may be disposed on a computer device, the computer device, for instance, located on board an electric aircraft or located remotely. In another embodiment, display 140 may be a flight display known in the art to be disposed in at least a portion of a cockpit of an electric aircraft. Visual alert 136 may comprise text. In an embodiment, for example, visual alert 136 may include a textual warning that an electrical short has been detected. A wide variety of possible textual warnings are possible. In another embodiment, visual alert 136 may include a warning sign such as a flashing symbol or other icon designed to alert the user to the problem. In some embodiments, processor 132 may be configured to send an audio alert. Sending an audio alert may include sending a signal to a speaker, or sending a signal to another device to trigger the audio alert. In some embodiments, there may be a speaker electrically connected to processor 132. In other embodiments, the speaker may be remote. As a non-limiting example, the speaker may be disposed on a charging device (e.g. charger 128). As another non-limiting example, the speaker may be disposed on a mobile device such as a smartphone or tablet. In some embodiments, both visual alert 136 and the audio alert may be transmitted via either a wired or wireless connection.

With continued reference to FIG. 1, processor 132 may, in some embodiments, be configured to calculate the total electricity usage of the charger 320. For the purposes of this disclosure, “total electricity usage” may include the total energy consumed while charging a single electric vehicle, or the total energy consumed over a set time period such as a day, a month, or a year, for example. The electricity usage may be calculated by comparing the total energy contained in charger 128's energy storage devices before charging and after charging. In another embodiment, the electricity usage may be calculated by monitoring the current output by charger 128.

With continued reference to FIG. 1, processor 128 may, in some embodiments, be configured to calculate a value based on energy datum. As a non-limiting example, the value may represent the amount of energy consumed by charger 128 when charging a load. As another non-limiting example, the value may represent the total cost of energy consumed by charger 128 when charging a load. As another non-limiting example, the value may represent the total price of energy consumed by charger 128 when charging a load to be charged to a user of charger 128.

With continued reference to FIG. 1, charging connector, in some embodiments, may include a proximity detection pin 120. Processor 132 may receive a current datum from the proximity detection pin 120. In some embodiments, the proximity detection pin 120 may be electrically connected to the processor 132 to transmit current datum. Proximity detection pin 120 has no current flowing through it when charging connector 104 is not connected to a plug. Once charging connector 104 is connected to a plug, then proximity detection pin 120 will have current flowing through it, allowing for the controller to detect, using this current flow, that the charging connector 104 is connected to a plug. In some embodiments, current datum may be the measurement of the current passing through proximity detection pin. In some embodiments proximity detection pin 120 may have a current sensor that generates the current datum. In other embodiments, proximity detection sensor may be electrically connected to controller and controller may include a current sensor.

With continued reference to FIG. 1, charger 128 can include an energy storage device or plurality of energy storage devices. Charger 128 is electrically connected to charging connector 104. In some embodiments, charger 128 may be electrically connected to sensor 124. In some embodiments, charger may be communicatively connected to processor 132. “Communicatively connected,” for the purpose of this disclosure, means connected such that data can be transmitted, whether wirelessly or wired. As used in this disclosure, a “charger” is an electrical system and/or circuit that increases electrical energy in an energy store, for example a battery. In some embodiments, the energy storage device may be a battery. Charger 128 may provide AC and/or DC power to charging connector 312. In some embodiments, charger 128 may include the ability to provide an alternating current to direct current converter configured to convert an electrical charging current from an alternating current. As used in this disclosure, an “analog current to direct current converter” is an electrical component that is configured to convert analog current to digital current. An analog current to direct current (AC-DC) converter may include an analog current to direct current power supply and/or transformer. In some embodiments, charger 128 may have a connection to grid power component. Grid power component may be connected to an external electrical power grid. In some embodiments, grid power component may be configured to slowly charge one or more batteries in order to reduce strain on nearby electrical power grids. In one embodiment, grid power component may have an AC grid current of at least 450 amps. In some embodiments, grid power component may have an AC grid current of more or less than 450 amps. In one embodiment, grid power component may have an AC voltage connection of 480 Vac. In other embodiments, grid power component may have an AC voltage connection of above or below 480 Vac. Charger 128 may be consistent with the charger disclosed in U.S. application Ser. No. 17/477,987 filed on Sep. 17, 2021, titled “Systems and Methods for Adaptive Electric Vehicle reference. Additionally, charger 128 may be consistent with the charger disclosed in U.S. application Ser. No. 17/515,448 filed on Oct. 30, 2021, titled “Systems and Methods for an Immediate Shutdown of an Electric Vehicle Charger,” the entirety of which is hereby incorporated by reference. In some embodiments, charger 128 may draw power from the power grid.

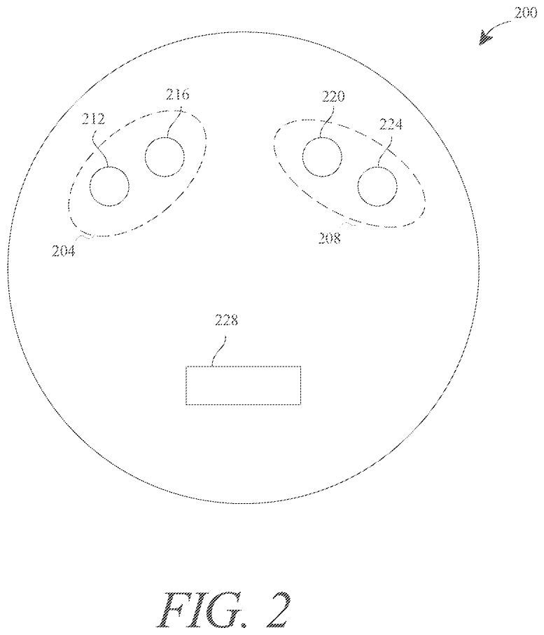

FIG. 2 is a depiction of the face of an embodiment of charging connector 200. Charging connector 200 may include AC pins 204. AC pins 204 carry AC power and may be consistent with any AC pin or pins previously disclosed in this disclosure. Charging connector 200 may include DC pins 208. DC pins 208 carry DC power and may be consistent with any DC pin or pins previously disclosed in this disclosure. AC pins 204 pins may include an AC live pin 212 and an AC return pin 216. AC live pin 212 may supply AC power to a load. AC return pin 216 may provide a return path for AC power from the load. DC pins 208 may include a DC live pin 220 and a DC return pin 224. DC live pin 220 may supply DC power to a load. DC return pin 224 may provide a return path for DC power from the load. Charging connector 200 may include a ground pin 228. Ground pin 228 is an electronic connector that is connected to ground. FIG. 2 is just one of many possible configurations for charging connector 200. For example, the locations of AC pins 204, DC pins 208, and ground pin 228 can be anywhere on the face of charging connector 200. The “face” of charging connector 200 is the portion of charging connector 200 adapted to mate with a corresponding charging port in an electric vehicle. Additionally, in some embodiments, there may be any number of live pins (e.g. AC live pin 212) and return pins (e.g. AC return pin 216). One of ordinary skill in the art, after viewing the entirety of this disclosure, would realize that there are a variety of possible configurations for charging connector 200.

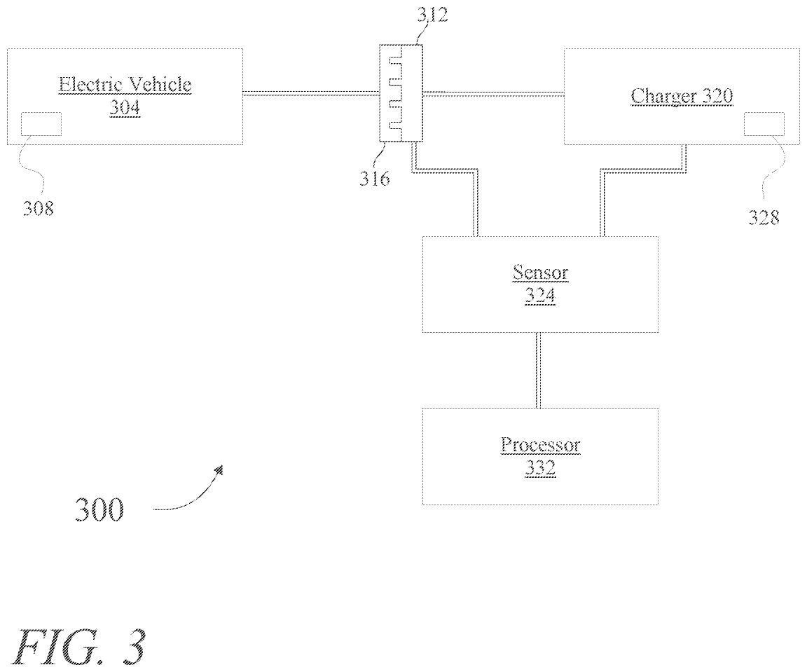

Referring to FIG. 3, FIG. 3 depicts an embodiment of charging system 300. Charging system 300 may include electric vehicle 304. In some embodiments, electric vehicle may contain a power source 308. Power source 308 may be electrically connected to charging port 312. In some embodiments, may be an energy storage device such as a battery or a plurality of batteries. Power source 308 may include an electrochemical cell configured to store potential electrical energy in the form of a chemical reaction. Power source 308 can be any energy storage element such as such as pouch cells, cylindrical cells, or electrochemical cells, for example. A battery may include, without limitation, a battery using nickel based chemistries such as nickel cadmium or nickel metal hydride, a battery using lithium ion battery chemistries such as a nickel cobalt aluminum (NCA), nickel manganese cobalt (NMC), lithium iron phosphate (LiFePO4), lithium cobalt oxide (LCO), and/or lithium manganese oxide (LMO), a battery using lithium polymer technology, lead-based batteries such as without limitation lead acid batteries, metal-air batteries, or any other suitable battery. Additionally, power source 308 need not be made up of only a single electrochemical cell, it can consist of several electrochemical cells wired in series or in parallel. Exemplary power sources are disclosed in detail in U.S. patent application Ser. Nos. 16/948,157 and 16/048,140 both entitled “SYSTEM AND METHOD FOR HIGH ENERGY DENSITY BATTERY MODULE”, which are incorporated in their entirety herein by reference.

With continued reference to FIG. 3, electric vehicle 304 may be electrically connected to charging port 312. Charging port 312 may be adapted to mate with charging connector 316. When charging port 312 is connected to charging connector 316, in some embodiments, power source 308 of electric vehicle 304 may be electrically connected to charger 320. When charging port 312 is disconnected from charging connector 316, then, in some embodiments. power source 308 may be not electrically connected to charger 320. Charging connector 316 may be electrically connected to charger 320. Additionally, in some embodiments, charging connector 316 may be electrically connected with sensor 324. Charging connector 316 may be consistent with any charging connector described in this disclosure.

With continued reference to FIG. 3, sensor 324 is configured to detect a charging characteristic of a communication. As used in this disclosure, a “sensor” is a device that is configured to detect an input and/or a phenomenon and transmit information related to the detection. Sensor 324 may be consistent with any other sensor described in this disclosure. For example, and without limitation, a sensor 324 may detect a phenomenon, such as a charging characteristic. As used in this disclosure, a “charging characteristic” is a detectable phenomenon associated with charging a power source 308. In one or more embodiments, a charging characteristic includes temperature, voltage, current, pressure, moisture, and the like. In one or more embodiments, sensor 324 may be configured to detect charging characteristic of a communication between charger 320 and electric vehicle 304 and then transmit a sensor output signal representative of charging characteristic, where the sensor signal includes a charging datum. As used in this disclosure, a “sensor signal” is a representation of a charging characteristic that sensor 324 may generate. Sensor signal may include charging datum. For instance, and without limitation, sensor 324 is configured to generate a charging datum of a communication. For the purposes of this disclosure, a “charging datum” is a datum representing a quantifiable element of data correlated to a charging characteristic. For example, and without limitation, power source 308 of electric vehicle 304 may need to be a certain temperature to operate properly; a charging datum may provide a numerical value, such as a temperature in degrees, that indicates the current temperature of a charging power source. For example, and without limitation, sensor 324 may be a temperature sensor that detects the temperature of a power source 308 of electric vehicle 304 to be at a numerical value of 100° F. and transmits the corresponding charging datum to, for example, processor 332. In another example, and without limitation, sensor 324 may be a current sensor and a voltage sensor that detects a current value and a voltage value, respectively, of power source 308 of an electric vehicle 304. Such charging datum may be associated with an operating condition of power source 308, and charger power source 328 such as, for example, a state of charge (SoC) or a depth of discharge (DoD) of the power source. For example, and without limitation, the charging datum may include, for example, a temperature, a state of charge, a moisture level, a state of health (or depth of discharge), or the like. A sensor signal may include any signal form described in this disclosure, for example digital, analog, optical, electrical, fluidic, and the like. In some cases, a sensor, a circuit, and/or a controller may perform one or more signal processing steps on a signal. For instance, sensor, circuit, and/or controller may analyze, modify, and/or synthesize a signal in order to improve the signal, for instance by improving transmission, storage efficiency, or signal to noise ratio.

Exemplary methods of signal processing may include analog, continuous time, discrete, digital, nonlinear, and statistical. Analog signal processing may be performed on non-digitized or analog signals. Exemplary analog processes may include passive filters, active filters, additive mixers, integrators, delay lines, compandors, multipliers, voltage-controlled filters, voltage-controlled oscillators, and phase-locked loops. Continuous-time signal processing may be used, in some cases, to process signals which varying continuously within a domain, for instance time. Exemplary non-limiting continuous time processes may include time domain processing, frequency domain processing (Fourier transform), and complex frequency domain processing. Discrete time signal processing may be used when a signal is sampled non-continuously or at discrete time intervals (i.e., quantized in time). Analog discrete-time signal processing may process a signal using the following exemplary circuits sample and hold circuits, analog time-division multiplexers, analog delay lines and analog feedback shift registers. Digital signal processing may be used to process digitized discrete-time sampled signals. Commonly, digital signal processing may be performed by a computing device or other specialized digital circuits, such as without limitation an application specific integrated circuit (ASIC), a field-programmable gate array (FPGA), or a specialized digital signal processor (DSP). Digital signal processing may be used to perform any combination of typical arithmetical operations, including fixed-point and floating-point, real-valued and complex-valued, multiplication and addition. Digital signal processing may additionally operate circular buffers and lookup tables. Further non-limiting examples of algorithms that may be performed according to digital signal processing techniques include fast Fourier transform (FFT), finite impulse response (FIR) filter, infinite impulse response (IIR) filter, and adaptive filters such as the Wiener and Kalman filters. Statistical signal processing may be used to process a signal as a random function (i.e., a stochastic process), utilizing statistical properties. For instance, in some embodiments, a signal may be modeled with a probability distribution indicating noise, which then may be used to reduce noise in a processed signal.

With continued reference to FIG. 3, in one or more embodiments, sensor 324 may include sensors configured to measure charging characteristics, such as physical and/or electrical parameters related to the charging connection between charging connector 316 and charging port 312. For example, and without limitation, sensor 324 may measure temperature and/or voltage, of battery modules and/or cells of power source 308 of electric vehicle 304 and/or charger power source 328 of charger 320. Sensor 324 may be configured to detect failure within each battery module, for instance and without limitation, as a function of and/or using detected charging characteristics. In one or more exemplary embodiments, battery cell failure may be characterized by a spike in temperature; sensor 324 may be configured to detect that increase in temperature and generate a corresponding signal, such as charging datum of the communication. In other exemplary embodiments, sensor 324 may detect voltage and direct the charging of individual battery cells according to charge level. Detection may be performed using any suitable component, set of components, and/or mechanism for direct or indirect measurement and/or detection of voltage levels, including without limitation comparators, analog to digital converters, any form of voltmeter, or the like.

With continued reference to FIG. 3, processor 332 is configured to receive a charging datum from sensor 324. Processor 332 may receive charging datum via a wired or wireless communication between processor 332 and sensor 324. In one or more embodiments, processor 332 is configured to determine a disruption element as a function of the received charging datum. For purposes of this disclosure, a “disruption element” is an element of information regarding a present-time failure, fault, or degradation of a condition or working order of a charging connection. In one or more embodiments, disruption element may be determined as a function of charging datum, as discussed further in this disclosure.

With continued reference to FIG. 3, in one or more embodiments, there may be outputs, such as charging datum, from sensor 324 or any other component present within charging system 300 may be analog or digital. Onboard or remotely located processors can convert those output signals from sensor 324 or sensor suite to a form that is usable by the destination of those signals, such as processor 332. The usable form of output signals from sensors, may be either digital, analog, a combination thereof, or an otherwise unstated form. Processing may be configured to trim, offset, or otherwise compensate the outputs of sensor suite. Based on sensor output, the processor can determine the output to send to downstream component. Processor 332 can include signal amplification, operational amplifier (Op-Amp), filter, digital/analog conversion, linearization circuit, current-voltage change circuits, resistance change circuits such as Wheatstone Bridge, an error compensator circuit, a combination thereof or otherwise undisclosed components. In some embodiments sensor 324 may be configured to communicate charging datum, for instance, by way of a network. Exemplary charging datum may include charging characteristics, for example, represented by way of at least a sensor signal. In some cases, charging datum may include one or more of a state of charge of a power source, a temperature of a power source, any other metric associated with power source health, temperature of ambient air, cost of electricity consumed, and the like.

With continued reference to FIG. 3, processor 332 is configured to disable the charging connection between charging connector 316 and charging port 312 based on disruption element. In one or more embodiments, if an immediate shutdown via a disablement of the charging connection is initiated, then processor 332 may also generate a signal to notify users, support personnel, safety personnel, flight crew, maintainers, operators, emergency personnel, aircraft computers, or a combination thereof. This signal may be consistent with any alert described in this disclosure. Charging system 300 may include a display. A display may be coupled to electric vehicle 304, charger 320, or a remote device. A display may be configured to show a disruption element to a user or to display an alert. The display may be consistent with any display described in this disclosure. In one or more embodiments, processor 332 may be configured to disable the charging connection based on the disruption element. For instance, and without limitation, processor 332 may be configured to detect a charge reduction event, defined for purposes of this disclosure as any temporary or permanent state of a battery cell requiring reduction or cessation of charging. A charge reduction event may include a cell being fully charged and/or a cell undergoing a physical and/or electrical process that makes continued charging at a current voltage and/or current level inadvisable due to a risk that the cell will be damaged, will overheat, or the like. Detection of a charge reduction event may include detection of a temperature of the cell above a preconfigured threshold, detection of a voltage and/or resistance level above or below a preconfigured threshold, or the like.

With continued reference to FIG. 3, in one or more embodiments, disruption element may indicate that power source 308 of electric vehicle 304 and/or charger power source 328 of charger 320, respectively, is operating outside of an acceptable operation condition represented by a preconfigured threshold (also referred to herein as a “threshold”). For the purposes of this disclosure, a “threshold” is a set desired range and/or value that, if exceeded by a value of charging datum, initiates a specific reaction of processor 332. A specific reaction may be, for example, a disablement command, which is discussed further below in this disclosure. Threshold may be set by, for example, a user or control circuit based on, for example, prior use or an input. In one or more embodiments, if charging datum is determined to be outside of a threshold, a disruption element is determined by processor 332 and a disablement command is generated. For example, and without limitation, charging datum may indicate that power source 308 of electric vehicle 304 and/or charger power source 328 of charger 320 has a temperature of 100° F. Such a temperature may be outside of a preconfigured threshold of, for example, 75° F. of an operational condition, such as temperature, of a power source and thus the charging connection may be disabled by processor 332 to prevent overheating of or permanent damage to power source 124,128. For the purposes of this disclosure, a “disablement command” is a signal transmitted to an electric vehicle and/or a charger providing instructions and/or a command to disable and/or terminate a charging connection between an electric vehicle and a charger, or providing instructions and/or a command to stop the metering process for the charging system 300. Disabling the charging connection may include terminating a communication between electric vehicle 304 and charger 320. For example, and without limitation, disabling the charging connection may include terminating a power supply to charger 320 so that charger 320 is no longer providing power to electric vehicle 304. In another example, and without limitation, disabling the charging connection may include terminating a power supply to electric vehicle 304. In another example, and without limitation, disabling the charging connection may include using a relay or switch between charger 320 and electric vehicle 304 to terminate charging connection and/or a communication between charger 320 and electric vehicle 304. Stopping the metering process may include stopping processor 332 from receiving an energy datum from sensor 324. Energy datum may be consistent with any energy datum discussed in this disclosure. Alternatively, stopping the metering process may include stopping processor 332 from generating an invoice or calculating a value based on the energy datum. In some embodiments, the value to be calculated may include the cost of the energy provided by the charger 320. Invoice may be consistent with any invoice discussed in this disclosure. In some embodiments, the disruption element may be “resolved.” For example, in embodiments where the disruption element indicates that power source 308 of electric vehicle 304 and/or charger power source 328 of charger 320, respectively, is operating outside of an acceptable operation condition represented by a preconfigured threshold, the disruption element may be resolved when power source 308 of electric vehicle 304 and/or charger power source 328 of charger 320 return to operating within an acceptable operation condition represented by the preconfigured threshold.

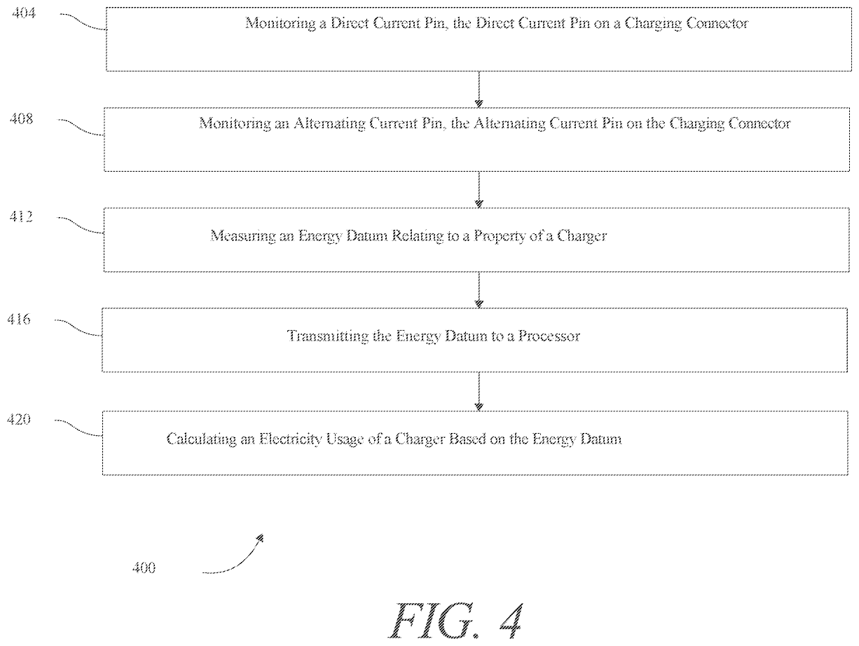

FIG. 4 depicts a flowchart of an embodiment for method 400. Method 400 includes a step 404 of monitoring a direct current pin, the direct current pin on a charging connector. Direct current pin may be consistent with any direct current pin described in this disclosure. Charging connector may be consistent with any charging connector described in this disclosure. Method 400 also includes a step 408 of monitoring an alternating current pin, the alternating current pin on the charging connector. Alternating current pin may be consistent with any alternating current pin described in this disclosure. Method 400 includes a step 412 of measuring an energy datum relating to a property of a charger. Energy datum may be consistent with any energy datum described as part of this disclosure. Charger may be consistent with any charger described as part of this disclosure. Method 400 includes a step 416 of transmitting the energy datum to a processor. Processor may be consistent with any processor described in this disclosure. Method 400 includes a step 420 of calculating an electricity usage of the charger based on the energy datum.

With continued reference to FIG. 4, in some embodiments, method 400 may include a step of generating an invoice based on the electricity usage of the charger. Invoice may be consistent with any invoice described in this disclosure. In some embodiments, the step of generating an invoice based on the electricity usage of the charger may include transmitting a second energy datum to the processor and subtracting the second energy datum from the first energy datum to calculate an energy datum difference. Second energy datum may be consistent with any second energy datum described in this disclosure. In some embodiments, step 412 of measuring an energy datum relating to a property of a charger may include measuring a current supplied by the charger. In some embodiments, step 412 of measuring an energy datum relating to a property of a charger may include measuring a stored energy of the charger.With continued reference to FIG. 4, in some embodiments, method 400 may include a step of transmitting the electricity usage of the charger to an external database. External database may be implemented, without limitation, as a relational database, a key-value retrieval database such as a NOSQL database, or any other format or structure for use as a database that a person skilled in the art would recognize as suitable upon review of the entirety of this disclosure. External database may alternatively or additionally be implemented using a distributed data storage protocol and/or data structure, such as a distributed hash table or the like. External database may include a plurality of data entries and/or records as described above. Data entries in a database may be flagged with or linked to one or more additional elements of information, which may be reflected in data entry cells and/or in linked tables such as tables related by one or more indices in a relational database. Persons skilled in the art, upon reviewing the entirety of this disclosure, will be aware of various ways in which data entries in a database may store, retrieve, organize, and/or reflect data and/or records as used herein, as well as categories and/or populations of data consistently with this disclosure.

In some embodiments, method 400 may include receiving a charging datum; determining a disruption element as a function of the charging datum; and stopping metering of the electricity usage of the charger based on the disruption element. Charging datum may be any charging datum described in this disclosure. Disruption element may be any disruption element described in this disclosure. In some embodiments, method 400 may include a step of notifying a user of the disruption element. This notification may be consistent with any notification or alert described in this disclosure.

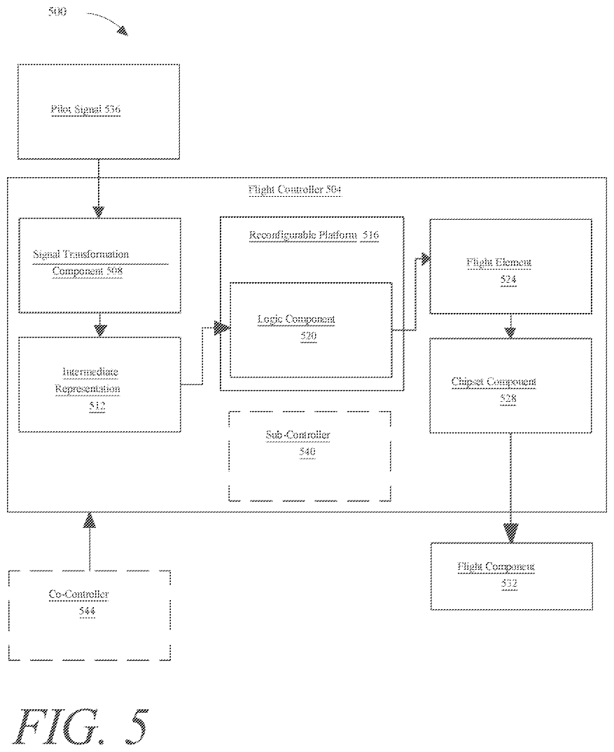

Now referring to FIG. 5, an exemplary embodiment 500 of a flight controller 504 is illustrated. As used in this disclosure a “flight controller” is a computing device of a plurality of computing devices dedicated to data storage, security, distribution of traffic for load balancing, and flight instruction. Flight controller 504 may include and/or communicate with any computing device as described in this disclosure, including without limitation a microcontroller, microprocessor, digital signal processor (DSP) and/or system on a chip (SoC) as described in this disclosure. Further, flight controller 504 may include a single computing device operating independently, or may include two or more computing device operating in concert, in parallel, sequentially or the like; two or more computing devices may be included together in a single computing device or in two or more computing devices. In embodiments, flight controller 504 may be installed in an aircraft, may control the aircraft remotely, and/or may include an element installed in the aircraft and a remote element in communication therewith.

In an embodiment, and still referring to FIG. 5, flight controller 504 may include a signal transformation component 508. As used in this disclosure a “signal transformation component” is a component that transforms and/or converts a first signal to a second signal, wherein a signal may include one or more digital and/or analog signals. For example, and without limitation, signal transformation component 508 may be configured to perform one or more operations such as preprocessing, lexical analysis, parsing, semantic analysis, and the like thereof. In an embodiment, and without limitation, signal transformation component 508 may include one or more analog-to-digital convertors that transform a first signal of an analog signal to a second signal of a digital signal. For example, and without limitation, an analog-to-digital converter may convert an analog input signal to a 10-bit binary digital representation of that signal. In another embodiment, signal transformation component 508 may include transforming one or more low-level languages such as, but not limited to, machine languages and/or assembly languages. For example, and without limitation, signal transformation component 508 may include transforming a binary language signal to an assembly language signal. In an embodiment, and without limitation, signal transformation component 508 may include transforming one or more high-level languages and/or formal languages such as but not limited to alphabets, strings, and/or languages. For example, and without limitation, high-level languages may include one or more system languages, scripting languages, domain-specific languages, visual languages, esoteric languages, and the like thereof. As a further non-limiting example, high-level languages may include one or more algebraic formula languages, business data languages, string and list languages, object-oriented languages, and the like thereof.

Still referring to FIG. 5, signal transformation component 508 may be configured to optimize an intermediate representation 512. As used in this disclosure an “intermediate representation” is a data structure and/or code that represents the input signal. Signal transformation component 508 may optimize intermediate representation as a function of a data-flow analysis, dependence analysis, alias analysis, pointer analysis, escape analysis, and the like thereof. In an embodiment, and without limitation, signal transformation component 508 may optimize intermediate representation 512 as a function of one or more inline expansions, dead code eliminations, constant propagation, loop transformations, and/or automatic parallelization functions. In another embodiment, signal transformation component 508 may optimize intermediate representation as a function of a machine dependent optimization such as a peephole optimization, wherein a peephole optimization may rewrite short sequences of code into more efficient sequences of code. Signal transformation component 508 may optimize intermediate representation to generate an output language, wherein an “output language,” as used herein, is the native machine language of flight controller 504. For example, and without limitation, native machine language may include one or more binary and/or numerical languages.

In an embodiment, and without limitation, signal transformation component 508 may include transform one or more inputs and outputs as a function of an error correction code. An error correction code, also known as error correcting code (ECC), is an encoding of a message or lot of data using redundant information, permitting recovery of corrupted data. An ECC may include a block code, in which information is encoded on fixed-size packets and/or blocks of data elements such as symbols of predetermined size, bits, or the like. Reed-Solomon coding, in which message symbols within a symbol set having q symbols are encoded as coefficients of a polynomial of degree less than or equal to a natural number k, over a finite field F with q elements; strings so encoded have a minimum hamming distance of k+1, and permit correction of (q-k-1)/2 erroneous symbols. Block code may alternatively or additionally be implemented using Golay coding, also known as binary Golay coding, Bose-Chaudhuri, Hocquenghuem (BCH) coding, multidimensional parity-check coding, and/or Hamming codes. An ECC may alternatively or additionally be based on a convolutional code.

In an embodiment, and still referring to FIG. 5, flight controller 504 may include a reconfigurable hardware platform 516. A “reconfigurable hardware platform,” as used herein, is a component and/or unit of hardware that may be reprogrammed, such that, for instance, a data path between elements such as logic gates or other digital circuit elements may be modified to change an algorithm, state, logical sequence, or the like of the component and/or unit. This may be accomplished with such flexible high-speed computing fabrics as field-programmable gate arrays (FPGAs), which may include a grid of interconnected logic gates, connections between which may be severed and/or restored to program in modified logic. Reconfigurable hardware platform 516 may be reconfigured to enact any algorithm and/or algorithm selection process received from another computing device and/or created using machine-learning processes.

Still referring to FIG. 5, reconfigurable hardware platform 516 may include a logic component 520. As used in this disclosure a “logic component” is a component that executes instructions on output language. For example, and without limitation, logic component may perform basic arithmetic, logic, controlling, input/output operations, and the like thereof. Logic component 520 may include any suitable processor, such as without limitation a component incorporating logical circuitry for performing arithmetic and logical operations, such as an arithmetic and logic unit (ALU), which may be regulated with a state machine and directed by operational inputs from memory and/or sensors; logic component 520 may be organized according to Von Neumann and/or Harvard architecture as a non-limiting example. Logic component 520 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC). In an embodiment, logic component 520 may include one or more integrated circuit microprocessors, which may contain one or more central processing units, central processors, and/or main processors, on a single metal-oxide-semiconductor chip. Logic component 520 may be configured to execute a sequence of stored instructions to be performed on the output language and/or intermediate representation 512. Logic component 520 may be configured to fetch and/or retrieve the instruction from a memory cache, wherein a “memory cache,” as used in this disclosure, is a stored instruction set on flight controller 504. Logic component 520 may be configured to decode the instruction retrieved from the memory cache to opcodes and/or operands. Logic component 520 may be configured to execute the instruction on intermediate representation 512 and/or output language. For example, and without limitation, logic component 520 may be configured to execute an addition operation on intermediate representation 512 and/or output language.

In an embodiment, and without limitation, logic component 520 may be configured to calculate a flight element 524. As used in this disclosure a “flight element” is an element of datum denoting a relative status of aircraft. For example, and without limitation, flight element 524 may denote one or more torques, thrusts, airspeed velocities, forces, altitudes, groundspeed velocities, directions during flight, directions facing, forces, orientations, and the like thereof. For example, and without limitation, flight element 524 may denote that aircraft is cruising at an altitude and/or with a sufficient magnitude of forward thrust. As a further non-limiting example, flight status may denote that is building thrust and/or groundspeed velocity in preparation for a takeoff. As a further non-limiting example, flight element 524 may denote that aircraft is following a flight path accurately and/or sufficiently.

Still referring to FIG. 5, flight controller 504 may include a chipset component 528. As used in this disclosure a “chipset component” is a component that manages data flow. In an embodiment, and without limitation, chipset component 528 may include a northbridge data flow path, wherein the northbridge dataflow path may manage data flow from logic component 520 to a high-speed device and/or component, such as a RAM, graphics controller, and the like thereof. In another embodiment, and without limitation, chipset component 528 may include a southbridge data flow path, wherein the southbridge dataflow path may manage data flow from logic component 520 to lower-speed peripheral buses, such as a peripheral component interconnect (PCI), industry standard architecture (ICA), and the like thereof. In an embodiment, and without limitation, southbridge data flow path may include managing data flow between peripheral connections such as ethernet, USB, audio devices, and the like thereof. Additionally or alternatively, chipset component 528 may manage data flow between logic component 520, memory cache, and a flight component 532. As used in this disclosure a “flight component” is a portion of an aircraft that can be moved or adjusted to affect one or more flight elements. For example, flight component532 may include a component used to affect the aircrafts' roll and pitch which may comprise one or more ailerons. As a further example, flight component 532 may include a rudder to control yaw of an aircraft. In an embodiment, chipset component 528 may be configured to communicate with a plurality of flight components as a function of flight element 524. For example, and without limitation, chipset component 528 may transmit to an aircraft rotor to reduce torque of a first lift propulsor and increase the forward thrust produced by a pusher component to perform a flight maneuver.

In an embodiment, and still referring to FIG. 5, flight controller 504 may be configured generate an autonomous function. As used in this disclosure an “autonomous function” is a mode and/or function of flight controller 504 that controls aircraft automatically. For example, and without limitation, autonomous function may perform one or more aircraft maneuvers, take offs, landings, altitude adjustments, flight leveling adjustments, turns, climbs, and/or descents. As a further non-limiting example, autonomous function may adjust one or more airspeed velocities, thrusts, torques, and/or groundspeed velocities. As a further non-limiting example, autonomous function may perform one or more flight path corrections and/or flight path modifications as a function of flight element 524. In an embodiment, autonomous function may include one or more modes of autonomy such as, but not limited to, autonomous mode, semi-autonomous mode, and/or non-autonomous mode. As used in this disclosure “autonomous mode” is a mode that automatically adjusts and/or controls aircraft and/or the maneuvers of aircraft in its entirety. For example, autonomous mode may denote that flight controller 504 will adjust the aircraft. As used in this disclosure a “semi-autonomous mode” is a mode that automatically adjusts and/or controls a portion and/or section of aircraft. For example, and without limitation, semi-autonomous mode may denote that a pilot will control the propulsors, wherein flight controller 504 will control the ailerons and/or rudders. As used in this disclosure “non-autonomous mode” is a mode that denotes a pilot will control aircraft and/or maneuvers of aircraft in its entirety.

In an embodiment, and still referring to FIG. 5, flight controller 504 may generate autonomous function as a function of an autonomous machine-learning model. As used in this disclosure an “autonomous machine-learning model” is a machine-learning model to produce an autonomous function output given flight element 524 and a pilot signal 536 as inputs; this is in contrast to a non-machine learning software program where the commands to be executed are determined in advance by a user and written in a programming language. As used in this disclosure a “pilot signal” is an element of datum representing one or more functions a pilot is controlling and/or adjusting. For example, pilot signal 536 may denote that a pilot is controlling and/or maneuvering ailerons, wherein the pilot is not in control of the rudders and/or propulsors. In an embodiment, pilot signal 536 may include an implicit signal and/or an explicit signal. For example, and without limitation, pilot signal 536 may include an explicit signal, wherein the pilot explicitly states there is a lack of control and/or desire for autonomous function. As a further non-limiting example, pilot signal 536 may include an explicit signal directing flight controller 504 to control and/or maintain a portion of aircraft, a portion of the flight plan, the entire aircraft, and/or the entire flight plan. As a further non-limiting example, pilot signal 536 may include an implicit signal, wherein flight controller 504 detects a lack of control such as by a malfunction, torque alteration, flight path deviation, and the like thereof. In an embodiment, and without limitation, pilot signal 536 may include one or more explicit signals to reduce torque, and/or one or more implicit signals that torque may be reduced due to reduction of airspeed velocity. In an embodiment, and without limitation, pilot signal 536 may include one or more local and/or global signals. For example, and without limitation, pilot signal 536 may include a local signal that is transmitted by a pilot and/or crew member. As a further non-limiting example, pilot signal 536 may include a global signal that is transmitted by air traffic control and/or one or more remote users that are in communication with the pilot of aircraft. In an embodiment, pilot signal 536 may be received as a function of a tri-state bus and/or multiplexor that denotes an explicit pilot signal should be transmitted prior to any implicit or global pilot signal.

Still referring to FIG. 5, autonomous machine-learning model may include one or more autonomous machine-learning processes such as supervised, unsupervised, or reinforcement machine-learning processes that flight controller 504 and/or a remote device may or may not use in the generation of autonomous function. As used in this disclosure “remote device” is an external device to flight controller 504. Additionally or alternatively, autonomous machine-learning model may include one or more autonomous machine-learning processes that a field-programmable gate array (FPGA) may or may not use in the generation of autonomous function. Autonomous machine-learning process may include, without limitation machine learning processes such as simple linear regression, multiple linear regression, polynomial regression, support vector regression, ridge regression, lasso regression, elasticnet regression, decision tree regression, random forest regression, logistic regression, logistic classification, K-nearest neighbors, support vector machines, kernel support vector machines, naïve bayes, decision tree classification, random forest classification, K-means clustering, hierarchical clustering, dimensionality reduction, principal component analysis, linear discriminant analysis, kernel principal component analysis, Q-learning, State Action Reward State Action (SARSA), Deep-Q network, Markov decision processes, Deep Deterministic Policy Gradient (DDPG), or the like thereof.

In an embodiment, and still referring to FIG. 5, autonomous machine learning model may be trained as a function of autonomous training data, wherein autonomous training data may correlate a flight element, pilot signal, and/or simulation data to an autonomous function. For example, and without limitation, a flight element of an airspeed velocity, a pilot signal of limited and/or no control of propulsors, and a simulation data of required airspeed velocity to reach the destination may result in an autonomous function that includes a semi-autonomous mode to increase thrust of the propulsors. Autonomous training data may be received as a function of user-entered valuations of flight elements, pilot signals, simulation data, and/or autonomous functions. Flight controller 504 may receive autonomous training data by receiving correlations of flight element, pilot signal, and/or simulation data to an autonomous function that were previously received and/or determined during a previous iteration of generation of autonomous function. Autonomous training data may be received by one or more remote devices and/or FPGAs that at least correlate a flight element, pilot signal, and/or simulation data to an autonomous function. Autonomous training data may be received in the form of one or more user-entered correlations of a flight element, pilot signal, and/or simulation data to an autonomous function.

Still referring to FIG. 5, flight controller 504 may receive autonomous machine-learning model from a remote device and/or FPGA that utilizes one or more autonomous machine learning processes, wherein a remote device and an FPGA is described above in detail. For example, and without limitation, a remote device may include a computing device, external device, processor, FPGA, microprocessor and the like thereof. Remote device and/or FPGA may perform the autonomous machine-learning process using autonomous training data to generate autonomous function and transmit the output to flight controller 504. Remote device and/or FPGA may transmit a signal, bit, datum, or parameter to flight controller 504 that at least relates to autonomous function. Additionally or alternatively, the remote device and/or FPGA may provide an updated machine-learning model. For example, and without limitation, an updated machine-learning model may be comprised of a firmware update, a software update, an autonomous machine-learning process correction, and the like thereof. As a non-limiting example a software update may incorporate a new simulation data that relates to a modified flight element. Additionally or alternatively, the updated machine learning model may be transmitted to the remote device and/or FPGA, wherein the remote device and/or FPGA may replace the autonomous machine-learning model with the updated machine-learning model and generate the autonomous function as a function of the flight element, pilot signal, and/or simulation data using the updated machine-learning model. The updated machine-learning model may be transmitted by the remote device and/or FPGA and received by flight controller 504 as a software update, firmware update, or corrected autonomous machine-learning model. For example, and without limitation autonomous machine learning model may utilize a neural net machine-learning process, wherein the updated machine-learning model may incorporate a gradient boosting machine-learning process.

Still referring to FIG. 5, flight controller 504 may include, be included in, and/or communicate with a mobile device such as a mobile telephone or smartphone. Further, flight controller may communicate with one or more additional devices as described below in further detail via a network interface device. The network interface device may be utilized for commutatively connecting a flight controller to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. The network may include any network topology and can may employ a wired and/or a wireless mode of communication.

In an embodiment, and still referring to FIG. 5, flight controller 504 may include, but is not limited to, for example, a cluster of flight controllers in a first location and a second flight controller or cluster of flight controllers in a second location. Flight controller 504 may include one or more flight controllers dedicated to data storage, security, distribution of traffic for load balancing, and the like. Flight controller 504 may be configured to distribute one or more computing tasks as described below across a plurality of flight controllers, which may operate in parallel, in series, redundantly, or in any other manner used for distribution of tasks or memory between computing devices. For example, and without limitation, flight controller 504 may implement a control algorithm to distribute and/or command the plurality of flight controllers. As used in this disclosure a “control algorithm” is a finite sequence of well-defined computer implementable instructions that may determine the flight component of the plurality of flight components to be adjusted. For example, and without limitation, control algorithm may include one or more algorithms that reduce and/or prevent aviation asymmetry. As a further non-limiting example, control algorithms may include one or more models generated as a function of a software including, but not limited to Simulink by MathWorks, Natick, Mass., USA. In an embodiment, and without limitation, control algorithm may be configured to generate an auto-code, wherein an “auto-code,” is used herein, is a code and/or algorithm that is generated as a function of the one or more models and/or software's. In another embodiment, control algorithm may be configured to produce a segmented control algorithm. As used in this disclosure a “segmented control algorithm” is control algorithm that has been separated and/or parsed into discrete sections. For example, and without limitation, segmented control algorithm may parse control algorithm into two or more segments, wherein each segment of control algorithm may be performed by one or more flight controllers operating on distinct flight components.

In an embodiment, and still referring to FIG. 5, control algorithm may be configured to determine a segmentation boundary as a function of segmented control algorithm. As used in this disclosure a “segmentation boundary” is a limit and/or delineation associated with the segments of the segmented control algorithm. For example, and without limitation, segmentation boundary may denote that a segment in the control algorithm has a first starting section and/or a first ending section. As a further non-limiting example, segmentation boundary may include one or more boundaries associated with an ability of flight component 532. In an embodiment, control algorithm may be configured to create an optimized signal communication as a function of segmentation boundary. For example, and without limitation, optimized signal communication may include identifying the discrete timing required to transmit and/or receive the one or more segmentation boundaries. In an embodiment, and without limitation, creating optimized signal communication further comprises separating a plurality of signal codes across the plurality of flight controllers. For example, and without limitation the plurality of flight controllers may include one or more formal networks, wherein formal networks transmit data along an authority chain and/or are limited to task-related communications. As a further non-limiting example, communication network may include informal networks, wherein informal networks transmit data in any direction. In an embodiment, and without limitation, the plurality of flight controllers may include a chain path, wherein a “chain path,” as used herein, is a linear communication path comprising a hierarchy that data may flow through. In an embodiment, and without limitation, the plurality of flight controllers may include an all-channel path, wherein an “all-channel path,” as used herein, is a communication path that is not restricted to a particular direction. For example, and without limitation, data may be transmitted upward, downward, laterally, and the like thereof. In an embodiment, and without limitation, the plurality of flight controllers may include one or more neural networks that assign a weighted value to a transmitted datum. For example, and without limitation, a weighted value may be assigned as a function of one or more signals denoting that a flight component is malfunctioning and/or in a failure state.

Still referring to FIG. 5, the plurality of flight controllers may include a master bus controller. As used in this disclosure a “master bus controller” is one or more devices and/or components that are connected to a bus to initiate a direct memory access transaction, wherein a bus is one or more terminals in a bus architecture. Master bus controller may communicate using synchronous and/or asynchronous bus control protocols. In an embodiment, master bus controller may include flight controller 504. In another embodiment, master bus controller may include one or more universal asynchronous receiver-transmitters (UART). For example, and without limitation, master bus controller may include one or more bus architectures that allow a bus to initiate a direct memory access transaction from one or more buses in the bus architectures. As a further non-limiting example, master bus controller may include one or more peripheral devices and/or components to communicate with another peripheral device and/or component and/or the master bus controller. In an embodiment, master bus controller may be configured to perform bus arbitration. As used in this disclosure “bus arbitration” is method and/or scheme to prevent multiple buses from attempting to communicate with and/or connect to master bus controller. For example and without limitation, bus arbitration may include one or more schemes such as a small computer interface system, wherein a small computer interface system is a set of standards for physical connecting and transferring data between peripheral devices and master bus controller by defining commands, protocols, electrical, optical, and/or logical interfaces. In an embodiment, master bus controller may receive intermediate representation 512 and/or output language from logic component 520, wherein output language may include one or more analog-to-digital conversions, low bit rate transmissions, message encryptions, digital signals, binary signals, logic signals, analog signals, and the like thereof described above in detail.

Still referring to FIG. 5, master bus controller may communicate with a slave bus. As used in this disclosure a “slave bus” is one or more peripheral devices and/or components that initiate a bus transfer. For example, and without limitation, slave bus may receive one or more controls and/or asymmetric communications from master bus controller, wherein slave bus transfers data stored to master bus controller. In an embodiment, and without limitation, slave bus may include one or more internal buses, such as but not limited to a/an internal data bus, memory bus, system bus, front-side bus, and the like thereof. In another embodiment, and without limitation, slave bus may include one or more external buses such as external flight controllers, external computers, remote devices, printers, aircraft computer systems, flight control systems, and the like thereof.

In an embodiment, and still referring to FIG. 5, control algorithm may optimize signal communication as a function of determining one or more discrete timings. For example, and without limitation master bus controller may synchronize timing of the segmented control algorithm by injecting high priority timing signals on a bus of the master bus control. As used in this disclosure a “high priority timing signal” is information denoting that the information is important. For example, and without limitation, high priority timing signal may denote that a section of control algorithm is of high priority and should be analyzed and/or transmitted prior to any other sections being analyzed and/or transmitted. In an embodiment, high priority timing signal may include one or more priority packets. As used in this disclosure a “priority packet” is a formatted unit of data that is communicated between the plurality of flight controllers. For example, and without limitation, priority packet may denote that a section of control algorithm should be used and/or is of greater priority than other sections.

Still referring to FIG. 5, flight controller 504 may also be implemented using a “shared nothing” architecture in which data is cached at the worker, in an embodiment, this may enable scalability of aircraft and/or computing device. Flight controller 504 may include a distributer flight controller. As used in this disclosure a “distributer flight controller” is a component that adjusts and/or controls a plurality of flight components as a function of a plurality of flight controllers. For example, distributer flight controller may include a flight controller that communicates with a plurality of additional flight controllers and/or clusters of flight controllers. In an embodiment, distributed flight control may include one or more neural networks. For example, neural network also known as an artificial neural network, is a network of “nodes,” or data structures having one or more inputs, one or more outputs, and a function determining outputs based on inputs. Such nodes may be organized in a network, such as without limitation a convolutional neural network, including an input layer of nodes, one or more intermediate layers, and an output layer of nodes. Connections between nodes may be created via the process of “training” the network, in which elements from a training dataset are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 5, a node may include, without limitation a plurality of inputs xᵢ that may receive numerical values from inputs to a neural network containing the node and/or from other nodes. Node may perform a weighted sum of inputs using weights wᵢ that are multiplied by respective inputs xᵢ. Additionally or alternatively, a bias b may be added to the weighted sum of the inputs such that an offset is added to each unit in the neural network layer that is independent of the input to the layer. The weighted sum may then be input into a function φ, which may generate one or more outputs y. Weight wᵢ applied to an input xᵢ may indicate whether the input is “excitatory,” indicating that it has strong influence on the one or more outputs y, for instance by the corresponding weight having a large numerical value, and/or a “inhibitory,” indicating it has a weak effect influence on the one more inputs y, for instance by the corresponding weight having a small numerical value. The values of weights wᵢ may be determined by training a neural network using training data, which may be performed using any suitable process as described above. In an embodiment, and without limitation, a neural network may receive semantic units as inputs and output vectors representing such semantic units according to weights wᵢ that are derived using machine-learning processes as described in this disclosure.

Still referring to FIG. 5, flight controller may include a sub-controller 540. As used in this disclosure a “sub-controller” is a controller and/or component that is part of a distributed controller as described above; for instance, flight controller 504 may be and/or include a distributed flight controller made up of one or more sub-controllers. For example, and without limitation, sub-controller 540 may include any controllers and/or components thereof that are similar to distributed flight controller and/or flight controller as described above. Sub-controller 540 may include any component of any flight controller as described above. Sub-controller 540 may be implemented in any manner suitable for implementation of a flight controller as described above. As a further non-limiting example, sub-controller 540 may include one or more processors, logic components and/or computing devices capable of receiving, processing, and/or transmitting data across the distributed flight controller as described above. As a further non-limiting example, sub-controller 540 may include a controller that receives a signal from a first flight controller and/or first distributed flight controller component and transmits the signal to a plurality of additional sub-controllers and/or flight components.

Still referring to FIG. 5, flight controller may include a co-controller 544. As used in this disclosure a “co-controller” is a controller and/or component that joins flight controller 504 as components and/or nodes of a distributer flight controller as described above. For example, and without limitation, co-controller 544 may include one or more controllers and/or components that are similar to flight controller 504. As a further non-limiting example, co-controller 544 may include any controller and/or component that joins flight controller 504 to distributer flight controller. As a further non-limiting example, co-controller 544 may include one or more processors, logic components and/or computing devices capable of receiving, processing, and/or transmitting data to and/or from flight controller 504 to distributed flight control system. Co-controller 544 may include any component of any flight controller as described above. Co-controller 544 may be implemented in any manner suitable for implementation of a flight controller as described above.

In an embodiment, and with continued reference to FIG. 5, flight controller 504 may be designed and/or configured to perform any method, method step, or sequence of method steps in any embodiment described in this disclosure, in any order and with any degree of repetition. For instance, flight controller 504 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Flight controller may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

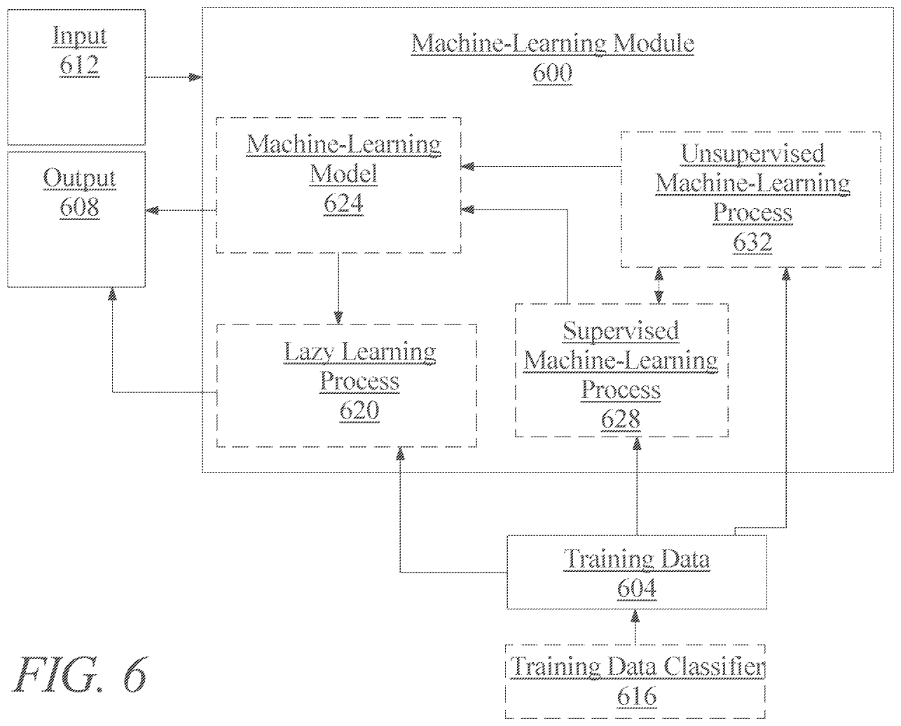

Referring now to FIG. 6, an exemplary embodiment of a machine-learning module 600 that may perform one or more machine-learning processes as described in this disclosure is illustrated. Machine-learning module may perform determinations, classification, and/or analysis steps, methods, processes, or the like as described in this disclosure using machine learning processes. A “machine learning process,” as used in this disclosure, is a process that automatedly uses training data 604 to generate an algorithm that will be performed by a computing device/module to produce outputs 608 given data provided as inputs 612; this is in contrast to a non-machine learning software program where the commands to be executed are determined in advance by a user and written in a programming language.

Still referring to FIG. 6, “training data,” as used herein, is data containing correlations that a machine-learning process may use to model relationships between two or more categories of data elements. For instance, and without limitation, training data 604 may include a plurality of data entries, each entry representing a set of data elements that were recorded, received, and/or generated together; data elements may be correlated by shared existence in a given data entry, by proximity in a given data entry, or the like. Multiple data entries in training data 604 may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data 604 according to various correlations; correlations may indicate causative and/or predictive links between categories of data elements, which may be modeled as relationships such as mathematical relationships by machine-learning processes as described in further detail below. Training data 604 may be formatted and/or organized by categories of data elements, for instance by associating data elements with one or more descriptors corresponding to categories of data elements. As a non-limiting example, training data 604 may include data entered in standardized forms by persons or processes, such that entry of a given data element in a given field in a form may be mapped to one or more descriptors of categories. Elements in training data 604 may be linked to descriptors of categories by tags, tokens, or other data elements; for instance, and without limitation, training data 604 may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

Alternatively or additionally, and continuing to refer to FIG. 6, training data 604 may include one or more elements that are not categorized; that is, training data 604 may not be formatted or contain descriptors for some elements of data. Machine-learning algorithms and/or other processes may sort training data 604 according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person's name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data 604 to be made applicable for two or more distinct machine-learning algorithms as described in further detail below. Training data 604 used by machine-learning module 600 may correlate any input data as described in this disclosure to any output data as described in this disclosure. As a non-limiting illustrative example flight elements and/or pilot signals may be inputs, wherein an output may be an autonomous function.

Further referring to FIG. 6, training data may be filtered, sorted, and/or selected using one or more supervised and/or unsupervised machine-learning processes and/or models as described in further detail below; such models may include without limitation a training data classifier 616. Training data classifier 616 may include a “classifier,” which as used in this disclosure is a machine-learning model as defined below, such as a mathematical model, neural net, or program generated by a machine learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. Machine-learning module 600 may generate a classifier using a classification algorithm, defined as a processes whereby a computing device and/or any module and/or component operating thereon derives a classifier from training data 604. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher's linear discriminant, quadratic classifiers, decision trees, boosted trees, random forest classifiers, learning vector quantization, and/or neural network-based classifiers. As a non-limiting example, training data classifier 416 may classify elements of training data to sub-categories of flight elements such as torques, forces, thrusts, directions, and the like thereof.

Still referring to FIG. 6, machine-learning module 600 may be configured to perform a lazy-learning process 620 and/or protocol, which may alternatively be referred to as a “lazy loading” or “call-when-needed” process and/or protocol, may be a process whereby machine learning is conducted upon receipt of an input to be converted to an output, by combining the input and training set to derive the algorithm to be used to produce the output on demand. For instance, an initial set of simulations may be performed to cover an initial heuristic and/or “first guess” at an output and/or relationship. As a non-limiting example, an initial heuristic may include a ranking of associations between inputs and elements of training data 604. Heuristic may include selecting some number of highest-ranking associations and/or training data 604 elements. Lazy learning may implement any suitable lazy learning algorithm, including without limitation a K-nearest neighbors algorithm, a lazy naïve Bayes algorithm, or the like; persons skilled in the art, upon reviewing the entirety of this disclosure, will be aware of various lazy-learning algorithms that may be applied to generate outputs as described in this disclosure, including without limitation lazy learning applications of machine-learning algorithms as described in further detail below.

Alternatively or additionally, and with continued reference to FIG. 6, machine-learning processes as described in this disclosure may be used to generate machine-learning models 624. A “machine-learning model,” as used in this disclosure, is a mathematical and/or algorithmic representation of a relationship between inputs and outputs, as generated using any machine-learning process including without limitation any process as described above, and stored in memory; an input is submitted to a machine-learning model 624 once created, which generates an output based on the relationship that was derived. For instance, and without limitation, a linear regression model, generated using a linear regression algorithm, may compute a linear combination of input data using coefficients derived during machine-learning processes to calculate an output datum. As a further non-limiting example, a machine-learning model 624 may be generated by creating an artificial neural network, such as a convolutional neural network comprising an input layer of nodes, one or more intermediate layers, and an output layer of nodes. Connections between nodes may be created via the process of “training” the network, in which elements from a training data 604 set are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 6, machine-learning algorithms may include at least a supervised machine-learning process 628. At least a supervised machine-learning process 628, as defined herein, include algorithms that receive a training set relating a number of inputs to a number of outputs, and seek to find one or more mathematical relations relating inputs to outputs, where each of the one or more mathematical relations is optimal according to some criterion specified to the algorithm using some scoring function. For instance, a supervised learning algorithm may include flight elements and/or pilot signals as described above as inputs, autonomous functions as outputs, and a scoring function representing a desired form of relationship to be detected between inputs and outputs; scoring function may, for instance, seek to maximize the probability that a given input and/or combination of elements inputs is associated with a given output to minimize the probability that a given input is not associated with a given output. Scoring function may be expressed as a risk function representing an “expected loss” of an algorithm relating inputs to outputs, where loss is computed as an error function representing a degree to which a prediction generated by the relation is incorrect when compared to a given input-output pair provided in training data 604. Persons skilled in the art, upon reviewing the entirety of this disclosure, will be aware of various possible variations of at least a supervised machine-learning process 628 that may be used to determine relation between inputs and outputs. Supervised machine-learning processes may include classification algorithms as defined above.

Further referring to FIG. 6, machine learning processes may include at least an unsupervised machine-learning processes 632. An unsupervised machine-learning process, as used herein, is a process that derives inferences in datasets without regard to labels; as a result, an unsupervised machine-learning process may be free to discover any structure, relationship, and/or correlation provided in the data. Unsupervised processes may not require a response variable; unsupervised processes may be used to find interesting patterns and/or inferences between variables, to determine a degree of correlation between two or more variables, or the like.

Still referring to FIG. 6, machine-learning module 600 may be designed and configured to create a machine-learning model 624 using techniques for development of linear regression models. Linear regression models may include ordinary least squares regression, which aims to minimize the square of the difference between predicted outcomes and actual outcomes according to an appropriate norm for measuring such a difference (e.g. a vector-space distance norm); coefficients of the resulting linear equation may be modified to improve minimization. Linear regression models may include ridge regression methods, where the function to be minimized includes the least-squares function plus term multiplying the square of each coefficient by a scalar amount to penalize large coefficients. Linear regression models may include least absolute shrinkage and selection operator (LASSO) models, in which ridge regression is combined with multiplying the least-squares term by a factor of 1 divided by double the number of samples. Linear regression models may include a multi-task lasso model wherein the norm applied in the least-squares term of the lasso model is the Frobenius norm amounting to the square root of the sum of squares of all terms. Linear regression models may include the elastic net model, a multi-task elastic net model, a least angle regression model, a LARS lasso model, an orthogonal matching pursuit model, a Bayesian regression model, a logistic regression model, a stochastic gradient descent model, a perceptron model, a passive aggressive algorithm, a robustness regression model, a Huber regression model, or any other suitable model that may occur to persons skilled in the art upon reviewing the entirety of this disclosure. Linear regression models may be generalized in an embodiment to polynomial regression models, whereby a polynomial equation (e.g. a quadratic, cubic or higher-order equation) providing a best predicted output/actual output fit is sought; similar methods to those described above may be applied to minimize error functions, as will be apparent to persons skilled in the art upon reviewing the entirety of this disclosure.

Continuing to refer to FIG. 6, machine-learning algorithms may include, without limitation, linear discriminant analysis. Machine-learning algorithm may include quadratic discriminate analysis. Machine-learning algorithms may include kernel ridge regression. Machine-learning algorithms may include support vector machines, including without limitation support vector classification-based regression processes. Machine-learning algorithms may include stochastic gradient descent algorithms, including classification and regression algorithms based on stochastic gradient descent. Machine-learning algorithms may include nearest neighbors algorithms. Machine-learning algorithms may include Gaussian processes such as Gaussian Process Regression. Machine-learning algorithms may include cross-decomposition algorithms, including partial least squares and/or canonical correlation analysis. Machine-learning algorithms may include naïve Bayes methods. Machine-learning algorithms may include algorithms based on decision trees, such as decision tree classification or regression algorithms. Machine-learning algorithms may include ensemble methods such as bagging meta-estimator, forest of randomized tress, AdaBoost, gradient tree boosting, and/or voting classifier methods. Machine-learning algorithms may include neural net algorithms, including convolutional neural net processes.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

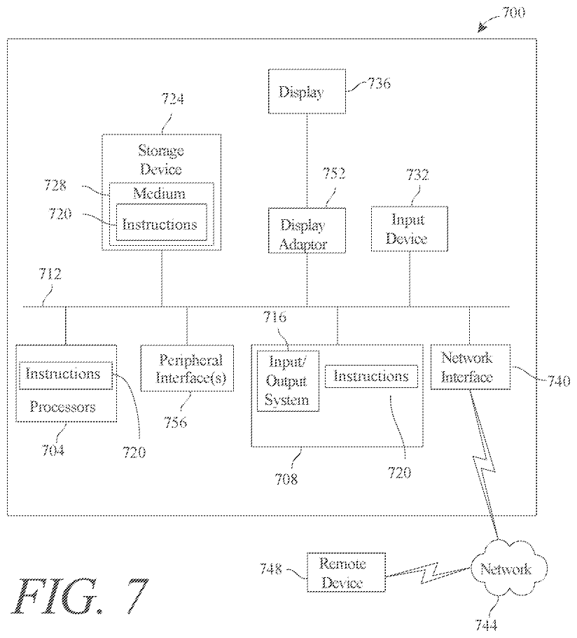

FIG. 7 shows a diagrammatic representation of one embodiment of a computing device in the exemplary form of a computer system 700 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 700 includes a processor 704 and a memory 708 that communicate with each other, and with other components, via a bus 712. Bus 712 may include any of several types of bus structures including, but not limited to, a memory bus, a memory controller, a peripheral bus, a local bus, and any combinations thereof, using any of a variety of bus architectures.

Processor 704 may include any suitable processor, such as without limitation a processor incorporating logical circuitry for performing arithmetic and logical operations, such as an arithmetic and logic unit (ALU), which may be regulated with a state machine and directed by operational inputs from memory and/or sensors; processor 704 may be organized according to Von Neumann and/or Harvard architecture as a non-limiting example. Processor 704 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC).

Memory 708 may include various components (e.g., machine-readable media) including, but not limited to, a random-access memory component, a read only component, and any combinations thereof. In one example, a basic input/output system 716 (BIOS), including basic routines that help to transfer information between elements within computer system 700, such as during start-up, may be stored in memory 708. Memory 708 may also include (e.g., stored on one or more machine-readable media) instructions (e.g., software) 720 embodying any one or more of the aspects and/or methodologies of the present disclosure. In another example, memory 708 may further include any number of program modules including, but not limited to, an operating system, one or more application programs, other program modules, program data, and any combinations thereof.

Computer system 700 may also include a storage device 724. Examples of a storage device (e.g., storage device 724) include, but are not limited to, a hard disk drive, a magnetic disk drive, an optical disc drive in combination with an optical medium, a solid-state memory device, and any combinations thereof. Storage device 724 may be connected to bus 712 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 724 (or one or more components thereof) may be removably interfaced with computer system 700 (e.g., via an external port connector (not shown)). Particularly, storage device 724 and an associated machine-readable medium 728 may provide nonvolatile and/or volatile storage of machine-readable instructions, data structures, program modules, and/or other data for computer system 700. In one example, software 720 may reside, completely or partially, within machine-readable medium 728. In another example, software 720 may reside, completely or partially, within processor 704.

Computer system 700 may also include an input device 732. In one example, a user of computer system 700 may enter commands and/or other information into computer system 700 via input device 732. Examples of an input device 732 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 732 may be interfaced to bus 712 via any of a variety of interfaces (not shown) including, but not limited to, a serial interface, a parallel interface, a game port, a USB interface, a FIREWIRE interface, a direct interface to bus 712, and any combinations thereof. Input device 732 may include a touch screen interface that may be a part of or separate from display 736, discussed further below. Input device 732 may be utilized as a user selection device for selecting one or more graphical representations in a graphical interface as described above.

A user may also input commands and/or other information to computer system 700 via storage device 724 (e.g., a removable disk drive, a flash drive, etc.) and/or network interface device 740. A network interface device, such as network interface device 740, may be utilized for connecting computer system 700 to one or more of a variety of networks, such as network 744, and one or more remote devices 748 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 744, may employ a wired and/or a wireless mode of communication. In general, any network topology may be used. Information (e.g., data, software 720, etc.) may be communicated to and/or from computer system 700 via network interface device 740.

Computer system 700 may further include a video display adapter 752 for communicating a displayable image to a display device, such as display device 736. Examples of a display device include, but are not limited to, a liquid crystal display (LCD), a cathode ray tube (CRT), a plasma display, a light emitting diode (LED) display, and any combinations thereof. Display adapter 752 and display device 736 may be utilized in combination with processor 704 to provide graphical representations of aspects of the present disclosure. In addition to a display device, computer system 700 may include one or more other peripheral output devices including, but not limited to, an audio speaker, a printer, and any combinations thereof. Such peripheral output devices may be connected to bus 712 via a peripheral interface 756. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods and systems according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

1. An electric charging and metering device for electric aircraft, comprising:
a charging connector configured to connect a charger to an electric aircraft, the charging connector comprising:
a direct current pin; and
an alternating current pin;
a sensor, the sensor communicatively connected to the charging connector, the sensor configured to:
monitor the direct current pin and the alternating current pin;
measure an energy datum, the energy datum relating to a property of the charger, the charging connector electrically connected to the charger; and
transmit the energy datum to a processor; and
the processor, the processor configured to:
receive the energy datum;
calculate an electricity usage of the charger; and
display a visual alert when a resistance datum falls below a threshold resistance datum.

2. The electric charging and metering device of claim 1, wherein the energy datum represents a current supplied by the charging connector.

3. The electric charging and metering device of claim 1, wherein the energy datum represents a stored energy of the charger.

4. The electric charging and metering device of claim 1, wherein the processor is further configured to calculate a value associated with the energy datum.

5. The electric charging and metering device of claim 4, wherein calculating the value further comprises:
receiving a second energy datum; and
subtracting the second energy datum from the energy datum to calculate an energy datum difference.

6. The electric charging and metering device of claim 1, wherein the processor is further configured to transmit the electricity usage of the charger to an external database.

7. The electric charging and metering device of claim 1, wherein the sensor is a current sensor.

8. The electric charging and metering device of claim 1, wherein the sensor is an electronic battery sensor.

9. The electric charging and metering device of claim 1, wherein:
the sensor is further configured to transmit a charging datum to the processor; and
the processor is further configured to:
receive the charging datum;
determine a disruption element as a function of the charging datum; and
stop metering the electricity usage of the charger based on the disruption element.

10. The electric charging and metering device of claim 9, wherein the processor is further configured to notify a user of the disruption element.

11. The electric charging and metering device of claim 10, wherein notifying a user of the disruption element comprises sending a visual alert.

12. The electric charging and metering device of claim 9, wherein the processor is further configured to start metering the electricity usage of the charger when the disruption element is resolved.

13. A method of electric charger monitoring, comprising:
monitoring a direct current pin, the direct current pin on a charging connector;
monitoring an alternating current pin, the alternating current pin on the charging connector;
measuring an energy datum relating to a property of a charger;
transmitting the energy datum to a processor;
calculating an electricity usage of the charger based on the energy datum; and
displaying a visual alert when a resistance datum falls below a threshold resistance datum.

14. The method of electric charger monitoring of claim 13, comprising generating an invoice based on the electricity usage of the charger.

15. The method of electric charger monitoring of claim 14, wherein measuring an energy datum relating to a property of the charger comprises measuring a current supplied by the charger.

16. The method of electric charger monitoring of claim 14, wherein measuring an energy datum relating to a property of the charger comprises measuring a stored energy of the charger.

17. The method of electric charger monitoring of claim 16, wherein generating an invoice based on the electricity usage of the charger comprises:
transmitting a second energy datum to the processor; and
subtracting the second energy datum from the first energy datum to calculate an energy datum difference.

18. The method of electric charger monitoring of claim 13, further comprising transmitting the electricity usage of the charger to an external database.

19. The method of electric charger monitoring of claim 13, further comprising:
receiving a charging datum;
determining a disruption element as a function of the charging datum; and
stopping metering of the electricity usage of the charger based on the disruption element.

20. The method of electric charger monitoring of claim 19, further comprising notifying a user of the disruption element.
